(19) United States
(12) Patent Application Publication
(10) Pub. No.: US 2012/0119748 A1
(43) Pub. Date: May 17, 2012

(54) BATTERY VOLTAGE MEASUREMENT SYSTEM AND BATTERY VOLTAGE MEASUREMENT METHOD

(75) Inventor: Yuki Kodama, Miyazaki (JP)

(73) Assignee: LAPIS SEMICONDUCTOR CO., LTD., Tokyo (JP)

(21) Appl. No.: 13/297,361

(22) Filed: Nov. 16, 2011

(30) Foreign Application Priority Data
Nov. 16, 2010 (JP) 2010-256130

(51) Int. Cl. G01R 31/36

(52) U.S. Cl. 324/433

(57) ABSTRACT

The present invention provides a battery voltage measurement system and battery voltage measurement method that may reduce the size of the battery voltage measurement system. A regulator generates a constant voltage based on a battery voltage, and inputs the constant voltage to an analog input terminal of an AID converter. The battery voltage is directly inputted to a reference voltage terminal of the AID converter via a terminal (a pad). The A/D converter uses the battery voltage as a reference voltage, determines the level of the input voltage which is the constant voltage, in respect to the reference voltage, and outputs a conversion result. The conversion results increase with a decrease in the battery voltage. Accordingly, the battery voltage is measured and monitored by a processing section on the basis of the conversion results.

### CROSS-REFERENCE TO RELATED APPLICATION

This application claims priority under 35 USC 119 from Japanese Patent Application No. 2010-256130 filed on Nov. 16, 2010, the disclosure of which is incorporated by reference herein.

### BACKGROUND OF THE INVENTION

1. Field of the Invention

The present invention relates to a battery voltage measurement system and a battery voltage measurement method.

2. Description of the Related Art

Battery voltage measurement systems that measure battery voltages in order to monitor remaining charge amounts, changes in battery voltages, and the like, are commonly known.

For example, Japanese Patent Application Laid-Open (JP-A) No. 2010-35337 recites a battery voltage monitoring control device. This monitoring control device performs monitoring on the basis of results of comparing, with a comparator, a voltage value for which a battery voltage of a measurement target battery is resistance-divided by a variable voltage division circuit and a reference voltage that is generated by a reference voltage generator. The variable voltage division circuit is configured by a variable resistance and a fixed resistance that is connected in series with the variable resistance.

Hereinafter, a conventional battery voltage measurement system is described. FIG. 3 illustrates an example of general configuration of the conventional battery voltage measurement system. A battery voltage measurement system 100 includes an A/D converter 112, a regulator 114, a MOS transistor 111 and a division resistance 113 that is configured by two resistance elements R1 and R2. The regulator 114 generates a constant voltage Vreg. The MOS transistor 111 functions as a switching element. The two resistance elements R1 and R2 are connected in series with one another, and one end of the resistance elements is connected to a ground potential.

The A/D converter 112 outputs a conversion result Dout, which is digital data to which an input voltage Ain is digitized by reference to the reference voltage Vref.

When a battery voltage VDD is to be measured, the MOS transistor 111 is turned on. Via the MOS transistor 111, the battery voltage VDD of the battery that is the measurement target is resistance-divided by the division resistance 113. Then, the resistance-divided battery voltage VDD is inputted to the A/D converter 112 as the input voltage Ain. The relationship between the input voltage Ain and the battery voltage VDD can be represented as in the following expression (1).

Ain=R2/(R1+R2)×VDD (1)

Thus, the input voltage Ain decreases with a decrease in the battery voltage VDD.

The regulator 114 generates the constant voltage Vreg. The A/D converter 112 performs A/D conversion (analog-to-digital conversion) of the resistance-divided battery voltage VDD using the constant voltage Vreg as the reference voltage Vref, and outputs the conversion result Dout. In general, the conversion result Dout can be represented by the following expression (2).

Dout=Ain÷Vref×x (2)

(x denotes a value determined by the specifications of the A/D converter 112)

FIG. 4 illustrates a specific example of a change in value of the input voltage Ain, in respect to the reference voltage Vref. For this specific example, a case is illustrated in which the constant voltage Vreg =the reference voltage Vref=2.0 V and the input voltage Ain decreases from 1.7 V (at time t1) through 1.5 V (at time t2) to 1.2 V (at time t3).

At time t1, at which the input voltage Ain is 1.7 V, 1.7 V÷2.0 V≈0.85 and the conversion result Dout becomes 0.85×x. At time t2, at which the input voltage Ain has decreased to 1.5 V, 1.5 V÷2.0 V≈0.75 and the conversion result Dout becomes 0.75×x. At time t3, at which the input voltage Ain has decreased to 1.2 V, 1.2 V÷2.0 V≈0.6 and the conversion result Dout becomes 0.6×x. Thus, the conversion results Dout decrease with the decrease in the input voltage Ain.

Therefore, in the conventional A/D converter 112, the conversion result Dout decreases with a decrease in the battery voltage VDD.

Here, in order to suppress power consumption of the battery voltage VDD, the MOS transistor 111 is turned off when the battery voltage VDD is not being measured.

In the battery voltage measurement system 100, a processing section 116 configured by, for example, a personal computer or the like performs processing to compare the conversion results Dout with a pre-registered voltage or the like. Thus, the battery voltage measurement system 100 measures the battery voltage VDD and performs battery remaining charge amount monitoring and the like.

In general, the AID converter performs the conversion by determining what level the voltage of the input voltage Ain is, in respect to the reference voltage Vref which is the highest voltage. Therefore, the A/D converter may not be able to perform the AID conversion properly if the input voltage Ain exceeds the reference voltage Vref. Furthermore, if the input voltage Ain exceeds the reference voltage Vref, there is a risk of the device from breaking. Therefore, when the regulator 114 generates the constant voltage Vreg based on the battery voltage VDD, it is necessary to use the resistance-divided battery voltage VDD as the input voltage Ain so as to prevent the input voltage Ain exceeding the reference voltage Vref. Therefore, in the battery voltage measurement system 100 described above, it has been necessary to provide the division resistance 113 to resistance-divide the battery voltage VDD.

### SUMMARY OF THE INVENTION

The present invention provides a battery voltage measurement system and battery voltage measurement method that may reduce the size of the battery voltage measurement system.

A first aspect of the present invention is a battery voltage measurement system including: a voltage generation section that generates a constant voltage; and a conversion section that performs analog-to-digital conversion of the constant voltage by using a battery voltage, which is a voltage of a measurement target battery being and is inputted to the conversion section, as a reference voltage.

A second aspect of the present invention is a battery voltage measurement method including: generating a constant voltage; and performing analog-to-digital conversion of the generated constant voltage by using a battery voltage, which is a voltage of a measurement target battery, as a reference voltage.

According to the above aspects, the present invention may reduce the size of a battery voltage measurement system.

### BRIEF DESCRIPTION OF THE DRAWINGS

An exemplary embodiment of the present invention will be described in detail based on the following figures, wherein:

FIG. 1 is a circuit diagram illustrating a configuration of a battery voltage measurement system according to a present embodiment;

FIG. 2 is a diagram describing a specific example, in the battery voltage measurement system according to the present embodiment, of a change in value of an input voltage Ain, in respect to a reference voltage Vref;

FIG. 3 is a circuit diagram illustrating a configuration of a conventional battery voltage measurement system; and

FIG. 4 is a diagram describing a specific example, in the conventional battery voltage measurement system, of a change in value of an input voltage Ain, in respect to a reference voltage Vref.

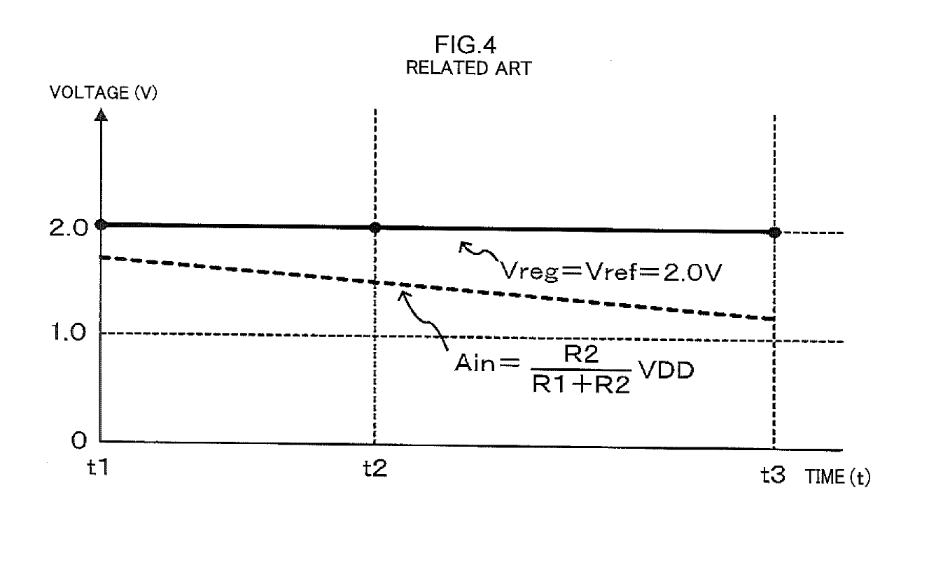

### DETAILED DESCRIPTION OF THE INVENTION

Herebelow, a battery voltage measurement system of a present embodiment is described in detail with reference to the attached drawings.

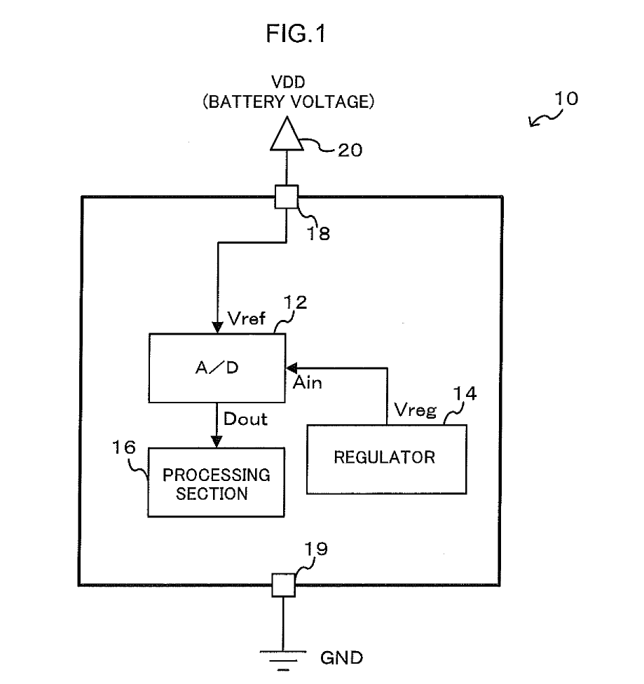

First, configuration of the battery voltage measurement system of the present embodiment is described. FIG. 1 illustrates an example of a configuration of the battery voltage measurement system of the present embodiment. A battery voltage measurement system 10 of the present embodiment as shown in FIG. 1 is provided with an A/D converter 12, a regulator 14 and a processing section 16. In the present embodiment, the A/D converter 12, the regulator 14 and the processing section 16 are configured as semiconductor integrated circuits which are formed on the same substrate 11.

The regulator 14 generates a constant voltage Vreg. In the regulator 14 of the present embodiment, the constant voltage Vreg is generated on the basis of a battery voltage VDD that is inputted from a battery power source 20 via a terminal (pad) 18. Note that wiring through which the battery voltage VDD is inputted is not illustrated in FIG. 1.

The A/D converter 12 A/D-converts (analog-to-digital conversion) an input voltage Ain with reference to a reference voltage Vref, and outputs a conversion result Dout which is a digital data. The battery voltage VDD is inputted from the battery power source 20 to a reference voltage terminal Vref of the A/D converter 12 via the terminal (pad) 18. The A/D converter 12 is connected to ground (GND) via a terminal (pad) 19. The constant voltage Vreg generated by the regulator 14 is inputted to an analog input terminal Ain of the A/D converter 12.

The A/D converter 12 of the present embodiment outputs the conversion result Dout, which is a digital conversion with reference to the reference voltage Vref of the input voltage Ain which equals to the constant voltage Vreg, in a range from the ground potential to the reference voltage Vref, which equals the battery voltage VDD. As a specific example, the conversion result Dout can be represented as in the following expression (3).

Dout=Ain÷Vref×x (3)

Note that x in expression (3) denotes a value determined by the specifications of the A/D converter 12. For example, if the A/D converter 12 converts the analog data input voltage Ain to 8-bit digital data, then x=256. Thus, the conversion results Dout change in accordance with the reference voltage Vref, which equals the battery voltage VDD.

The processing section 16 measures and monitors the battery voltage VDD in accordance with the conversion results Dout inputted thereto by the A/D converter 12. In the present embodiment, the processing section 16 includes a microcomputer. The microcomputer includes a central processing unit (CPU), a memory including ROM and RAM, and a non-volatile storage section constituted with flash memory or the like. The processing section 16 of the present embodiment has a voltage that is a reference for monitoring registered in the memory in advance, and processing that compares this voltage with the conversion results Dout is executed by the CPU. Accordingly, the processing section 16 of the present embodiment measures and monitors the battery voltage VDD.

Next, operation of the battery voltage measurement system 10 of the present embodiment is described.

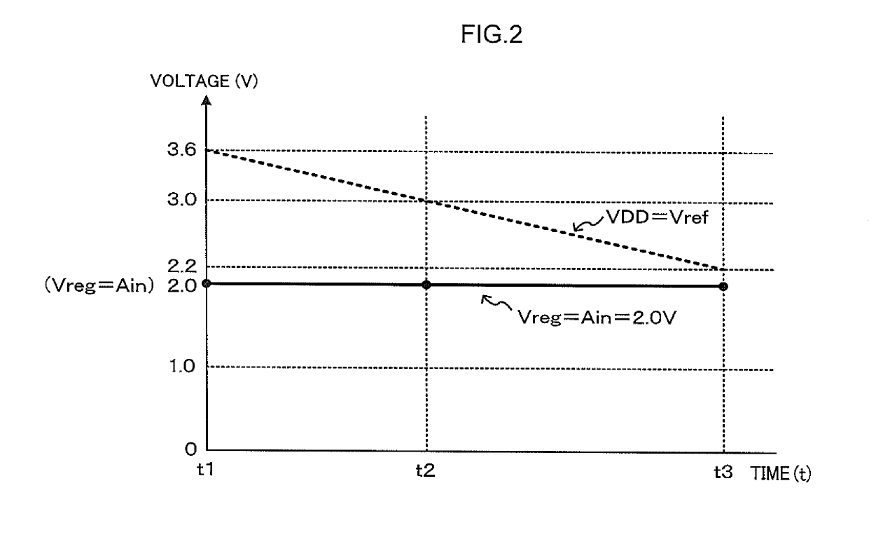

For the battery voltage measurement system 10 of the present embodiment, a diagram describing a specific example of a change in the value of the input voltage Ain, in respect to the reference voltage Vref, is illustrated in FIG. 2. For this specific example, a case is illustrated in which the constant voltage Vreg=the input voltage Ain=2.0 V, and the reference voltage Vref, which equals the battery voltage VDD, decreases from 3.6 V (at time t1) through 3.0 V (at time t2) to 2.2 V (at time t3).

At time t1, at which the battery voltage VDD is 3.6 V, 2 V÷3.6 V≈0.56 and the conversion result Dout becomes 0.56×x. At time t2, at which the battery voltage VDD has decreased to 3.0 V, 2 V÷3.0 V≈0.67 and the conversion result Dout becomes 0.67×x. At time t3, at which the battery voltage VDD has decreased to 2.2 V, 2 V÷2.2 V≈0.91 and the conversion result Dout becomes 0.91×x. Thus, the conversion results Dout increase with the decrease in the battery voltage VDD.

Thus, the processing section 16 of the present embodiment measures and monitors the battery voltage VDD in accordance with the increasing value of the conversion results Dout due to the decrease of the battery voltage VDD.

In the battery voltage measurement system 10 of the present embodiment, it is preferable for the constant voltage Vreg generated by the regulator 14 to be set to a lower value than a lower limit of a voltage monitoring range (measurement range) of the battery voltage VDD.

As described above, the A/D converter 12 of the present embodiment outputs the conversion result Dout, which is a digital conversion with reference to the reference voltage Vref of the input voltage Ain which equals to the constant voltage Vreg, in a range from the ground potential to the reference voltage Vref which equals to the battery voltage VDD. Therefore, the input voltage Ain must be within the range from the ground potential to the reference voltage Vref which is equal to the battery voltage VDD. If the input voltage Ain exceeds the reference voltage Vref, the A/D conversion may not be performed properly. Therefore, the input voltage Ain must be less than or equal to the reference voltage Vref for the A/D conversion to be properly performed,

In the present embodiment, the input voltage Ain is a constant value, and is the constant voltage Vreg. Therefore, when the battery voltage VDD decreases due to exhaustion of the battery power source 20 or the like, because the reference voltage Vref equals the battery voltage VDD, the input voltage Ain may become greater than the reference voltage Vref.

As another specific example, a case in which the battery voltage VDD to be monitored is in between 3.0 V to 2.0 V, is described. In this case, the monitoring range (measurement range) of the battery voltage VDD is 3.0 V to 2.0 V. The lower limit of this monitoring range is a voltage value that is required to start charging of the battery power source 20 and/or stop operation of applications that are driven by the battery power source 20, or the like. If the constant voltage Vreg here were 2.2 V, then when the battery voltage VDD decreases to 2.0 V, the input voltage Ain (the constant voltage Vreg, which is 2.2 V) would be greater than the reference voltage Vref (the battery voltage VDD, which is 2.0 V). As a result, the A/D converter 12 may not perform the A/D conversion properly.

Therefore, the constant voltage Vreg, which is the input voltage Ain, is to a value lower than the lower limit of the monitoring range of the battery voltage VDD, which is the lower limit of the changing reference voltage Vref. Accordingly, the input voltage Ain may be prevented from being greater than the reference voltage Vref.

As described above, in the battery voltage measurement system 10 of the present embodiment, the constant voltage Vreg generated in accordance with the battery voltage VDD by the regulator 14 is inputted to the analog input terminal Ain of the A/D converter 12, and the battery voltage VDD is directly inputted from the battery power source 20 to the reference voltage terminal of the A/D converter 12 via the terminal (pad) 18. The A/D converter 12 determines the level of the input voltage Ain which is the constant voltage Vreg, with the battery voltage VDD serving as the reference voltage Vref, and outputs the A/D-converted conversion result Dout. The conversion results Dout increase due to a decrease in the battery voltage VDD. Thus, the processing section 16 measures and monitors the battery voltage VDD on the basis of the conversion results Dout.

The regulator 14 generates the constant voltage Vreg on the basis of the battery voltage VDD. In the battery voltage measurement system 10 of the present embodiment, the constant voltage Vreg serves as the input voltage Ain. Therefore, the input voltage Ain will be lower than the battery voltage VDD. Thus, the present embodiment may make the input voltage Ain inputted to the A/D converter 12 lower than the reference voltage Vref which is the battery voltage VDD.

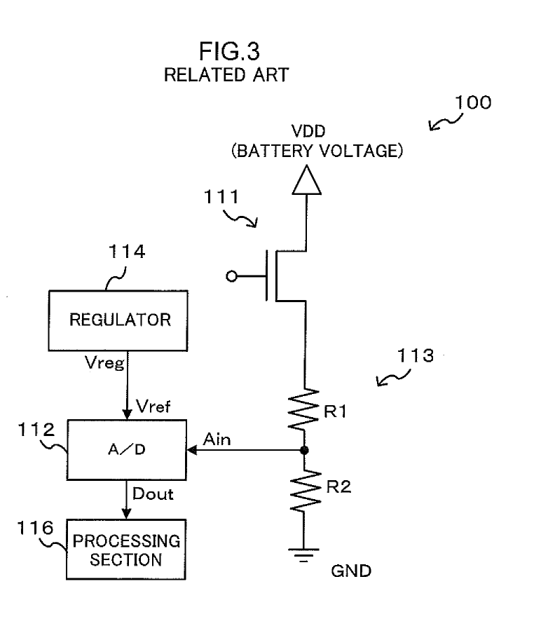

In the conventional battery voltage measurement system, the battery voltage VDD is resistance-divided by a division resistance, such that the input voltage Ain will not exceed the constant voltage Vreg which equals to the reference voltage Vref of the A/D converter, and an input voltage Ain lower than the battery voltage VDD is generated (see FIG. 3). In contrast, in the battery voltage measurement system 10 of the present embodiment as described above, there is no need to resistance-divide the battery voltage VDD. Therefore, a division resistance (the two resistance elements R1 and R2 connected in series with one end of the resistance element R2 connected to the ground potential), or a switching element that controls this divided resistance (a MOS transistor or the like) and the like is no need in the present embodiment. Accordingly, the present embodiment may reduce the size of the battery voltage measurement system 10.

In the conventional battery voltage measurement system, the battery voltage VDD is connected to the ground potential via the division resistance. In contrast, the present embodiment does not require this configuration, Therefore, in the present embodiment, current does not flow from the battery voltage VDD to the ground potential through the resistance element R2. Therefore, the present embodiment may suppress power consumption (exhaustion) of the battery voltage VDD.

Further, in the conventional battery voltage measurement system, in order to suppress power consumption of the battery voltage VDD, control to turn off the MOS transistor when measurement of the battery voltage VDD is not executed is required. In contrast, this control is not required in the battery voltage measurement system 10 of the present embodiment. Thus, in the present embodiment, operations relating to this control, such as matching timings of the battery voltage VDD measurement operation and the control operation and the like, are not required. Therefore, the present embodiment may implement a simpler battery voltage measurement operation. Moreover, the present embodiment does not require a control device to perform this control.

Furthermore, since a division resistance is not required in the battery voltage measurement system 10 of the present embodiment, variability of the resistance elements that configure the division resistance may not effect the reference voltage conversion results Dout. Therefore, the present embodiment may measure and monitor the battery voltage VDD more accurately.

In the present embodiment, the battery voltage measurement system is configured as a semiconductor integrated circuit in which the A/D converter 12, the regulator 14 and the processing section 16 are formed on the same substrate 11. However, the present invention is not limited thereto. For example, the processing section 16 may be formed on a separate substrate (external to a semiconductor integrated circuit in which the A/D converter 12 and the regulator 14 are formed). However, if the battery voltage measurement system 10 is formed on the same substrate 11, as in the present embodiment, there is no need for an output port or terminal (pad) for outputting the conversion result Dout to the exterior.

It is preferable for the regulator 14 not to be configured specifically for measurement and monitoring of the battery voltage VDD, but to be configured such that the regulator 14 may also be used as a regulator that generates the constant voltage Vreg that may be applied to another logic circuit or the like. According to such configuration, the size of a whole system may be further reduced.

The voltage values of the constant voltage Vreg and the like mentioned above are examples. It will be clear that alterations are possible within a scope not departing from the spirit of the present invention.

What is claimed is:

1. A battery voltage measurement system comprising:
a voltage generation section that generates a constant voltage; and
a conversion section that performs analog-to-digital conversion of the constant voltage by using a battery voltage, which is a voltage of a measurement target battery being and is inputted to the conversion section, as a reference voltage.

2. The battery voltage measurement system according to claim 1, wherein the voltage generation section generates a low voltage having a lower voltage value than the battery voltage.

3. The battery voltage measurement system according to claim 1, wherein the voltage value of the constant voltage has a lower voltage value than a lower limit of a predetermined measurement range of the battery voltage.

4. The battery voltage measurement system according to claim 1, further comprising a measurement section that measures the battery voltage on the basis of the constant voltage that has been analog-to-digital converted by the conversion section.

5. The battery voltage measurement system according to claim 1, wherein the voltage generation section generates the constant voltage on the basis of the battery voltage.

6. A battery voltage measurement method comprising:
generating a constant voltage; and
performing analog-to-digital conversion of the generated constant voltage by using a battery voltage, which is a voltage of a measurement target battery, as a reference voltage.

7. The battery voltage measurement method according to claim 6, further comprising measuring the battery voltage of the measurement target battery on the basis of the constant voltage that has been analog-to-digital converted.

8. The battery voltage measurement method according to claim 7, wherein the battery voltage is measured on the basis of the constant voltage that has been analog-to-digital converted and that increases in accordance with a decrease of the battery voltage.

9. The battery voltage measurement method according to claim 6, wherein the constant voltage is generated by lowering the battery voltage.

10. The battery voltage measurement method according to claim 6, wherein the constant voltage is lower in voltage value than the battery voltage.

11. The battery voltage measurement method according to claim 6, wherein the constant voltage is generated so as to be lower than a lower limit of a predetermined measurement range of the battery voltage.
